(19) United States
(12) Patent Application Publication
(10) Pub. No.: US 2007/0069230 A1
(43) Pub. Date: Mar. 29, 2007

(54) Light-emitting diode and light source device having same

(75) Inventor: Tai-Cherng Yu, Tu-Cheng (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI Precision Industry CO., LTD., Tu-Cheng City (TW)

(21) Appl. No.: 11/413,250

(22) Filed: Apr. 28, 2006

(30) Foreign Application Priority Data
Sep. 29, 2005 (CN) 200510100050.8

(51) Int. Cl. H01L 33/00

(52) U.S. Cl. 257/98

(57) ABSTRACT

A light-emitting diode (10) includes a light-emitting chip (12) and a light-permeable cover (16) arranged over the light-emitting chip. The cover has a central convex portion (162) and a peripheral portion (164) surrounding the convex portion. The convex portion is positioned above the light-emitting chip. The peripheral portion has an inner surface (166) and an outer surface (168). The outer surface is configured for reflecting and directing light emitted from the light-emitting chip to exit through the inner surface. By optical design with the convex portion and the peripheral portion of the cover, the light utilization ratio of the light-emitting diode is enhanced. Furthermore a light source device (40) using the light-emitting diode is also provided.

### BACKGROUND

1. Technical Field

The present invention generally relates to a light-emitting diode and a light source device having the same.

2. Discussion of Related Art

At present, fluorescence lamps are popularly utilized as illumination tools. However the mercury used in the fluorescence lamps represents a great danger to environment when the fluorescence lamps are damaged and/or reclaimed and so many researchers have suggested developing LEDs (light emitting diodes) to replace them. This would also have the advantage of greater convenience as the lifespan of LEDs is longer than that of fluorescent lamps and they would therefore not need to be replaced so often. Therefore using LED light sources to replace fluorescent lights has become seen as the way of the future.

Light-emitting diodes are semiconductor devices that can convert electrical energy directly into light, due to the nature of the recombination of electron and hole that occurs in the semiconductor solid. Light-emitting diodes rely on this recombination process to emit light.

However, for illumination, the light utilization ratio of conventional light-emitting diodes is low so that the effect of illumination is not satisfactory.

What is needed, therefore, is a light-emitting diode with a high light utilization ratio and a light source device using the same.

### SUMMARY

A light-emitting diode includes a light-emitting chip and a light-permeable cover arranged over the light-emitting chip. The cover has a central convex portion and a peripheral portion surrounding the convex portion. The convex portion is positioned directly above the light-emitting chip. The peripheral portion has an inner surface and an outer surface. The outer surface is configured for reflecting and directing light emitted from the light-emitting chip to exit through the inner surface.

A light source device includes a plurality of light-emitting diodes and an optical lens being disposed over light-emitting diodes. Each light-emitting diode includes a light-emitting chip and a light-permeable cover arranged over the light-emitting chip. The cover has a central convex portion and a peripheral portion surrounding the convex portion. The convex portion is positioned directly above the light-emitting chip. The peripheral portion has an inner surface and an outer surface. The outer surface is configured for reflecting and directing light emitted from the light-emitting chip to exit through the inner surface.

Other advantages and novel features will become more apparent from the following detailed description of the present invention, when taken in conjunction with the accompanying drawings.

### BRIEF DESCRIPTION OF THE DRAWINGS

Many aspects of the present light-emitting diode and its related light source device can be better understood with reference to the following drawings. The components in the drawings are not necessarily drawn to scale, the emphasis instead being placed upon clearly illustrating the principles of the present light-emitting diode and related light source device. Moreover, in the drawings, like reference numerals designate corresponding parts throughout the several views.

FIG. 1 is a schematic, sectional view of a light-emitting diode in according with a first preferred embodiment;

FIG. 2 is similar to FIG. 1, showing light paths associated with the light-emitting diode of FIG. 1, and

FIG. 3 a schematic, sectional view of a light source device in according with a second preferred embodiment.

Corresponding reference characters indicate corresponding parts throughout the drawing. The exemplifications set out herein illustrate at least one preferred embodiment of the present invention, in one form, and such exemplifications are not to be construed as limiting the scope of the invention in any manner.

### DETAILED DESCRIPTION OF PREFERRED EMBODIMENTS

Reference will now be made to the drawings to describe preferred embodiments of the present light-emitting diode and its related light source device, in detail.

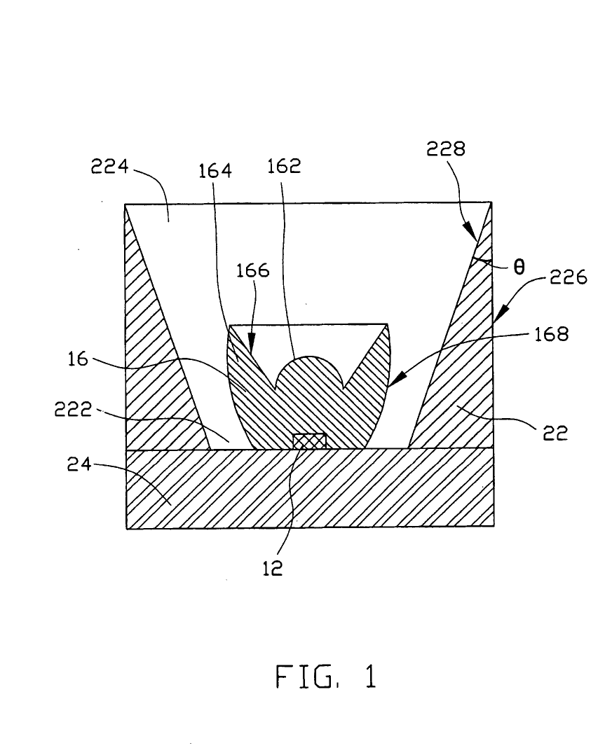

Referring to FIG. 1, a light-emitting diode 10, in accordance with a first preferred embodiment, is shown. The light-emitting diode 10 includes a light-emitting chip 12, a light-permeable cover 16, a reflector 22 and a printed circuit board 24.

The light-emitting chip 12 is for example a red light-emitting chip, a green light-emitting chip or a blue light-emitting chip. Fluorescent powders may be coated on the light-emitting chip 12 so that the light beams emitted from the light-emitting chip 12 excite the fluorescent powders to emit light beams. The light beams emitted from the fluorescent powders are mixed with the light beams emitted from the light-emitting chip 12 to obtain light beams of a color different to that of the light beams emitted from the light-emitting chip 12.

The cover 16 is generally transparent and is arranged over the light-emitting chip 12 and encloses the light-emitting chip 12 to insure normal operation of the light-emitting chip 12. The cover 16 is manufactured by an injection molding process or the like. Generally, the cover 16 is made of resin material, such as polyester, acrylic resin, fluororesin or polyvinyl chloride. Polyesters include polyethylene terephthalate (PET) and polyethylene naphthalate (PEN). Acrylic resins include polymethyl methacrylate and modified polymethyl methacrylate. Fluororesins include polyvinylidene fluoride (PVDF).

The cover 16 has a central convex portion 162 and a peripheral portion 164. The convex portion 162 is positioned above the light-emitting chip 12 and protrudes away from the light-emitting chip 12. In the present embodiment, the convex portion 162 is dome-like in shape. A surface of the convex portion 162 is a part of a spherical surface, preferably an aspheric surface. The peripheral portion 164 surrounds the convex portion 162 and has an inner surface 166 and an outer surface 168. The inner surface 166 of the peripheral portion 164 is configured to be conical. The outer surface 168 of the peripheral portion 164 is mainly configured in a manner so as to reflect and direct light beams emitted from the light-emitting chip 12 to exit through the inner surface 166 of the peripheral portion 164. In the illustrated exemplary embodiment, the outer surface 168 of the peripheral portion 164 is configured to be convex. A height of the peripheral portion 164 may be higher than that of the convex portion 162.

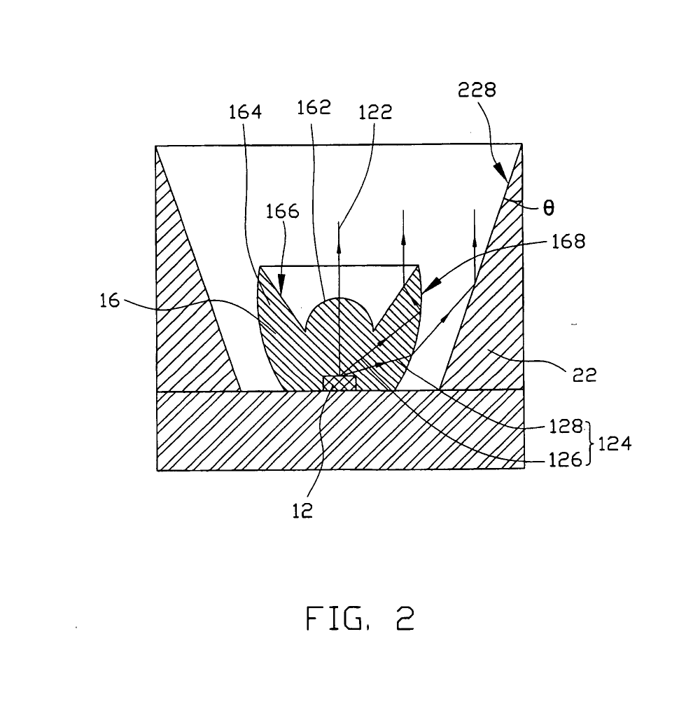

Referring to FIG. 2, this shows light paths associated with the light-emitting diode 10 of FIG. 1. The light-emitting chip 12 emits a plurality of first beams emitted toward the convex portion 162, and a plurality of second light beams 124 emitted toward the outer surface 168 of the peripheral portion 164. In order to simplify the description of the present embodiment, an exemplary first light beam 122 and a pair of second light beams 124 are illustrated. The second light beams 124 include a light beam 126 and a light beam 128. The light beam 126 of the second light beams 124 is incident on the cover 16 at such an angle as to undergo total internal reflection in the cover 16, the light beam 128 of the second light beams 124 is incident at such an angle as to be transmitted through the cover 16.

The first light beams pass directly through the convex portion 162 of the cover 16 to in a substantially parallel direction, such as a direction of illumination. Some of the second light beams 124, e.g. the light beam 126 is totally reflected by the outer surface 168 of the peripheral portion 164 onto the inner surface 166 of the peripheral portion 164 and then passes through the inner surface 166 of the peripheral portion 164 in the substantially parallel direction. Therefore, the brightness of light beams to the substantially parallel direction is enhanced and light utilization ratio of the light-emitting chip 12 is improved.

The reflector 22 is annular and may be made of metallic material, such as aluminum or copper. The annular reflector 22 surrounds the cover 16 and the light-emitting chip 12 therein. The reflector 22 has a first end defining a first opening 222 and a second end defining a second opening 224. The diameter of the second opening 224 is bigger than that of the first opening 222. The cover 16 and the light-emitting chip 12 are disposed adjacent to the first end with the reflector 22, the cover 16 and the light-emitting chip 12 being coaxial. The first end of the reflector 22, the cover 16 and the light-emitting chip 12 are connected to the printed circuit board 24 and the second end is positioned away from the printed circuit board 24. The reflector 22 has an outer surface 226 and an inner surface 228. The outer surface 226 of the reflector 22 intersects the inner surface 228 of the reflector 22 at an angle θ.

Referring to FIG. 2 again, some beams of the second light beams 124, e.g. the light beam 128 emitted from the light-emitting chip 12 passes through the outer surface 168 of the peripheral portion 164 and exits toward the inner surface 228 of the reflector 22 and then are reflected by the inner surface 228 of the reflector 22 towards the substantially parallel direction. Therefore, the brightness of light beams in the substantially parallel direction is further enhanced. Moreover, the brightness distribution of light beams emitted from the light-emitting chip 12 may be adjusted by changing the size of the angle θ.

The printed circuit board 24 is used for supporting the reflector 22, the cover 16 and the light-emitting chip 12 thereon. The light-emitting chip 12 is electrically connected to the printed circuit board 24.

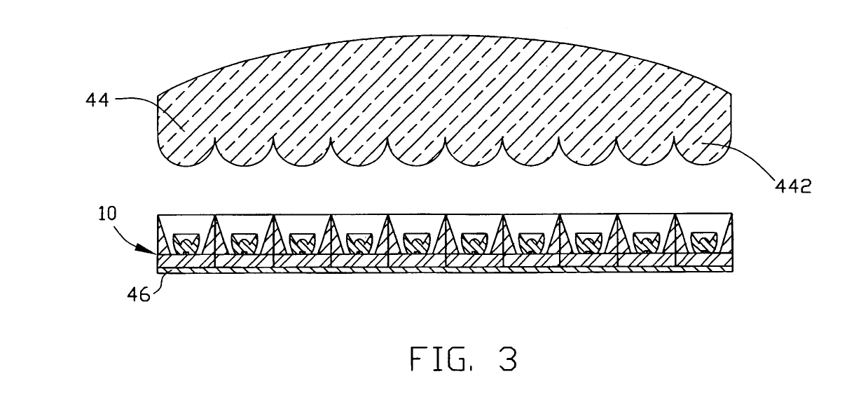

Referring to FIG. 3, a light source device 40, in accordance with a second preferred embodiment, is shown. The light source device 40 includes a plurality of light-emitting diodes 10, an optical lens 44 and a base 46. The plurality of light-emitting diodes 10 are the same as those in the first embodiment.

The plurality of light-emitting diodes 10 are arranged on the base 46 in an array. The optical lens 44 is disposed over the plurality of light-emitting diode 10. In this preferred embodiment, the optical lens 44 is an aspheric lens. A surface of the optical lens 44 facing away from the plurality of the light-emitting diodes 10 is aspheric. Another surface of the optical lens 44 close to the plurality of the light-emitting diode 10 has a plurality of projections 442 corresponding to the plurality of light-emitting diodes 10. The projections 442 may be dome-like in shape or strip-like in shape. The area of the optical lens 44 is close to or the same as that of the light-emitting diodes 10 array. The brightness distribution of light beams exiting from the optical lens 44 is more uniform.

Also variations may be made by replacing the aspheric lens with another lens, for example a Fresnel lens.

It is to be understood that the above-described embodiment is intended to illustrate rather than limit the invention. Variations may be made to the embodiment without departing from the spirit of the invention as claimed. The above-described embodiments are intended to illustrate the scope of the invention and not restrict the scope of the invention.

What is claimed is:

1. A light-emitting diode comprising:
a light-emitting chip, and
a light-permeable cover arranged over the light-emitting chip, the cover having a central convex portion and a peripheral portion surrounding the convex portion, the convex portion being positioned directly above the light-emitting chip, the peripheral portion having an inner surface and an outer surface, the outer surface being configured for reflecting and directing light emitted from the light-emitting chip to exit through the inner surface.

2. The light-emitting diode of claim 1, wherein the light-emitting chip is selected from the group consisting of a red light-emitting chip, a green light-emitting chip and a blue light-emitting chip.

3. The light-emitting diode of claim 1, wherein a material of the cover is chosen from the group consisting of resin materials or glasses.

4. The light-emitting diode of claim 3, wherein the resin material is selected from the group consisting of polyesters, acrylic resins, fluororesin and polyvinylchloride.

5. The light-emitting diode of claim 1, further comprising an annular reflector surrounding the cover and the light-emitting chip therein.

6. The light-emitting diode of claim 5, wherein the reflector has a first end defining a first opening and a second end defining a second opening, a diameter of the second opening is greater than that of the first opening, the cover and the light-emitting chip being disposed adjacent to the first end.

7. The light-emitting diode of claim 6, further comprising a printed circuit board for supporting the light-emitting diode thereon, the printed circuit board being electrically connected to the light-emitting chip.

8. A light source device comprising:
a plurality of light-emitting diodes, each light-emitting diode comprising a light-emitting chip; and a light-permeable cover arranged over the light-emitting chip, the cover having a central convex portion and a peripheral portion surrounding the convex portion, the convex portion being positioned directly above the light-emitting chip, the peripheral portion having an inner surface and an outer surface, the outer surface being configured for reflecting and directing light emitted from the light-emitting chip to exit through the inner surface; and
an optical lens disposed over the plurality of light-emitting diodes.

9. The light source device of claim 8, wherein the light-emitting chip is selected from the group consisting of a red light-emitting chips, a green light-emitting chips and a blue light-emitting chips.

10. The light source device of claim 8, wherein a material of the cover chosen from the group consisting of r esin materials and glasses.

11. The light source device of claim 10, wherein the resin material is selected from the group consisting of polyester, acrylic resin, fluororesin and polyvinylchloride.

12. The light-emitting diode of claim 8, further comprising an annular reflector surrounding the cover and the light-emitting chip therein.

13. The light-emitting diode of claim 12, wherein the reflector has a first end defining a first opening and a second end defining a second opening, a diameter of the second opening is greater than that of the first opening, the cover and the light-emitting chip being disposed adjacent to the first end.

14. The light-emitting diode of claim 13, further comprising a printed circuit board for supporting the light-emitting diode thereon, the printed circuit board being electrically connected to the light-emitting chip.

15. The light source device of claim 8, wherein the optical lens is chosen from the group consisting of aspheric lenses or a Fresnel lenses.

16. The light source device of claim 15, wherein the aspheric lens includes a plurality of projections facing and spatially corresponding to the plurality of light-emitting diodes.

17. The light source device of claim 16, wherein the projections are dome-like in shape or strip-like in shape.
